(19) United States
(12) Patent Application Publication
(10) Pub. No.: US 2007/0029991 A1
(43) Pub. Date: Feb. 8, 2007

(54) Vibration transducer using changes in polarization of light passing through an optical fiber

(76) Inventors: Cary R. Murphy, Hickory, NC (US); Mark H. Bridges, Hickory, NC (US); David E. Vokey, Sidney (CA)

Correspondence Address: ADE & COMPANY INC., 2157 Henderson Highway, WINNIPEG, MB, R2G1P9, CA

(21) Appl. No.: 11/461,897

(22) Filed: Aug. 2, 2006

Related U.S. Application Data
(60) Provisional application No. 60/704,927, filed on Aug. 3, 2005.

(51) Int. Cl. G01R 31/00

(52) U.S. Cl. 324/96

(57) ABSTRACT

An acoustic microphone includes a diaphragm attached to one part a detection coil portion of an optical fiber with another part attached to a fixed base member so that vibrations in the diaphragm cause twisting of parts of the fiber on either side of the coil to change polarization of light from a source of polarized light passing through the fiber. These changes are detected in a sensor defined by a polarizer tuned to be orthogonal to the source so that changes increase the intensity of light from a minimum at the tuned condition. An electronic sensor at an end of the fiber downstream of the detection portion is arranged to detect the changes in the light and convert the changes into an output signal representative of the vibrations monitored. The vibrations are detected only by the detection portion by providing a tuneable polarizer at the entrance to the detection coil and by providing a multimode fiber which is not responsive to the vibrations to carry the light to the sensor.

This application claims the benefit of the priority date under 35USC119 from Provisional Application 60/704,927 filed 3 Aug. 2005.

The present invention relates to an apparatus for the detection of vibration such as acoustical energy by using changes in polarization of light passing through a single mode optical fiber.

### BACKGROUND OF THE INVENTION

Reference is made to the following which may provide prior art and or further information, the disclosure of which is incorporated herein by reference:

U.S. Pat. No. 4,389,090 Fiber Optic Polarization Controller, Herve C. LeFevre, Los Altos Cailf., 1983

Christian Hentschel, FIBER OPTICS HANDBOOK, pp 18-20, Hewlett Packard GmbH, Second Edition.

### SUMMARY OF THE INVENTION

According to the present invention, there is provided an apparatus comprising:

a vibration responsive member arranged to receive vibrations to be monitored;

a fixed base member;

an optical fiber having a detection portion mounted between the base member and the vibration responsive member;

a source of light for transmission along the fiber and through the portion;

the portion of the fiber being arranged such that vibration of the vibration responsive member relative to the base member causes changes in the light transmitted through the portion;

an electronic sensor at an end of the fiber downstream of the detection portion arranged to detect the changes in the light and convert the changes into an output signal representative of the vibrations monitored.

In a particularly preferred end use of this apparatus, the apparatus is a microphone for detecting acoustic vibrations, the vibration responsive member is a diaphragm and the electronic sensor is arranged to emit an electronic audio signal.

Preferably the light is polarized and the detection portion of the fiber connected between the vibration responsive member and the base member is arranged such that the vibrations cause a twist in a part of the fiber so as to change polarization of the light.

Preferably the detection portion of the fiber comprises a coil and parts of the fiber either side of the coil such that movement of the coil causes twist in the parts.

Preferably the coil is planar with tangential legs thereof forming the parts where the legs are attached to one of the base member and the vibration responsive member and a part of the coil diametrically opposite the legs is attached to the other such that the vibration causes twisting of the legs.

In one arrangement, the source comprises a source of polarized light and a transport portion of the fiber which carries the polarized light to the detection portion.

As an alternative arrangement, the source comprises a source of non-polarized light and a transport fiber which carries the polarized light to the detection portion and wherein there is provided a polarizer between the transport fiber and the detection portion of the fiber so as to create a polarized light source at the input to the detection portion and to remove any effects of vibration on the transport fiber.

Preferably the polarizer is a rotatable polarizer controlled by a controller for initial or periodic tuning of the angle of polarization of the light.

Preferably the electronic sensor includes a polarizer arranged such that the intensity of light transmitted thereby changes as the polarization of the light passing through the detection portion changes.

Preferably the polarizer is arranged such that the intensity of light passing therethrough is at a minimum when the detection portion is undistorted by vibration.

As a particularly preferred technique, there is provided an optical splitter downstream of the detection portion which feeds two signals into a pair of optical polarizers whose state of polarization is aligned orthogonal to each other and the polarization of the light from the source is tuned such that the intensity output of one polarizer is at a maximum signal when the detection portion is undistorted by vibration and thus aligned with the polarization of the source and such that the other polarizer is at a minimum and thus orthogonal to the polarization of the source and the other polarizer is used to detect the changes in polarization caused by the vibration.

Preferably there is provided a return portion of fiber extending from the detection portion to the electronic sensor and wherein the return portion is a multimode fiber rather than single mode fiber so as to remove any effects of vibration on the return fiber.

Preferably the method makes the fiber sensitive to polarization rotation based on rotation and sensitive to attenuation caused by compression. The fiber is sensitive to attenuation caused by compression because the fibers are loops and the compression changes the macro-bending by deforming the circular character of the loop. This causes a portion to be above the minimum angle for macro-bending, and a portion to be below the portion tighter than minimum angle is lossier than the loop originally was., The fiber is thus made sensitive to acoustic excitation by attaching to a diaphragm.

The fundamental concept of the transducer exploits the tendency of single mode optical fiber to exhibit birefringence when stressed, and for that birefringence to cause a shift in state of polarization as a function of said stress. In linear polarized light, when light is incident upon a polarization filter (polarizer) whose axis of polarization is orthogonal to the polarization of the light, the light will be blocked by an amount called the extinction ratio of the polarizer. If the light is aligned with the polarizer, it will pass through. A polarizer, therefore, can be used as a filter, rejecting one orientation of linear polarization while passing the other.

A polarized light source (PLS) is launched into the fiber transducer. On the far end, a rotatable polarizer (RP) is adjusted orthogonal to that of the received steady state light in order to create a null at the detector/preamp (Rx). Any physical activity which disturbs the state of polarization will appear as a signal at that Rx.

### BRIEF DESCRIPTION OF THE DRAWINGS

One embodiment of the invention will now be described in conjunction with the accompanying drawings in which:

FIG. 1 illustrates a block diagram of a basic system according to the present invention where a polarized light source launched into a length of single mode fiber transducer which is connected to an optical polarizer, which in turn feeds an optical receiver and processor.

FIG. 2 is a block diagram of an enhanced system according to the present invention with orthogonal polarization alignment, used for enhanced alignment of polarization.

FIGS. 3A, 3B and 3C are a schematic illustrations of a fiber optic loop shaped for use in the systems of FIGS. 1 and 2.

FIG. 4A is a front elevational view of the loop of FIG. 3 as attached to the diaphragm to form the transducer.

FIG. 4B is a side elevational view of the loop of FIG. 3 as attached to the diaphragm to form the transducer.

FIG. 5 is a Block diagram of a further enhanced system similar to that of FIG. 1 which uses a remote polarization rotator system with a non-polarized laser source.

In the drawings like characters of reference indicate corresponding parts in the different figures.

### DETAILED DESCRIPTION

Reference is made to the above patent of LeFevre, the disclosure of which is incorporated herein by reference which discloses a construction which is particularly useful in forming an optical fiber construction suitable for detecting acoustic energy.

A light source of stable polarization 1 is launched into a single mode fiber 2. At the remote or receive end the single mode fiber 2 is connected to the input of an optical polarizer 3. This polarizer passes light with similarly aligned polarization, and blocks light orthogonally aligned. The output of this polarizer is connected to an optical receiver 4 by way of optical fiber 5. Physical excitation of the transducer fiber causes a local mechanical disturbance to the fiber. This mechanical disturbance, while not introducing detectable macro or micro bending losses, causes the polarization orientation of the light transmitted through the fiber to change. This results in a change in the optical power at the output port 5 which feeds the receiver. The resultant optical signal is proportional in amplitude to the disturbing forces.

Assuming the polarizer is tuned so as to be orthogonal to the polarization of the light when undisturbed by vibration, any rotation in polarization caused by vibration now will cause the power to increase. Acoustic sound pressure causes a diaphragm to perturb the optical fiber, thereby shifting the state of polarization. Electronics detect that shift and convert it to an audio signal.

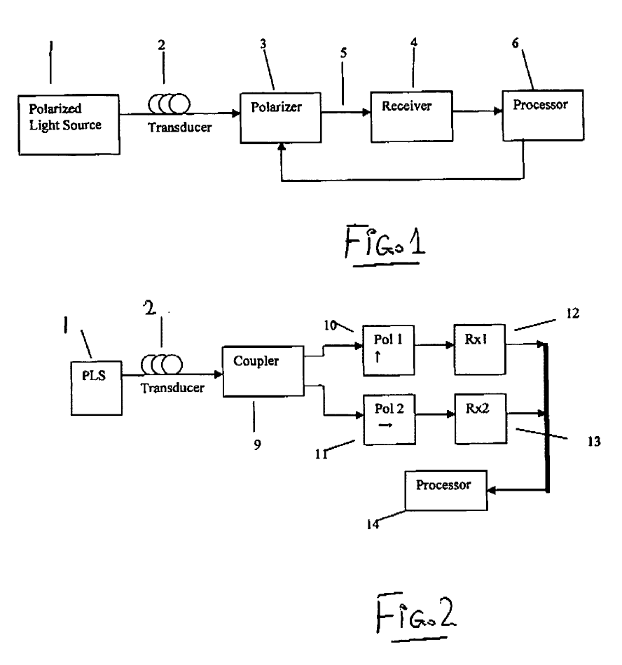

Turning now to FIG. 2, an enhanced embodiment consists of launching a light source of stable polarization 1 into a single mode fiber 2 as in FIG. 1. At the remote or receive end the single mode fiber is connected to the input of an optical splitter or coupler 9, typically of a 50:50 split ratio. The two output legs of this coupler feeds a pair of optical polarizers 10 and 11, whose state of polarization (SOP) is aligned orthogonal to each other. These feed a pair of optical receivers 12 and 13.

In order to maximize detection sensitivity the optics must be aligned such that the signal at receiver 13 is at a minimum; that is the polarization of the second polarizer 11 is perfectly orthogonal to the light. This signal is, however, very low in magnitude and difficult to measure. One way of insuring this alignment is to align the first polarizer 10 for a maximum signal at receiver 12. In this manner, the small signal of the null of polarizer 11 can be tuned by maximizing the signal from polarizer 10. The output of receiver 13 is then the desired audio signal.

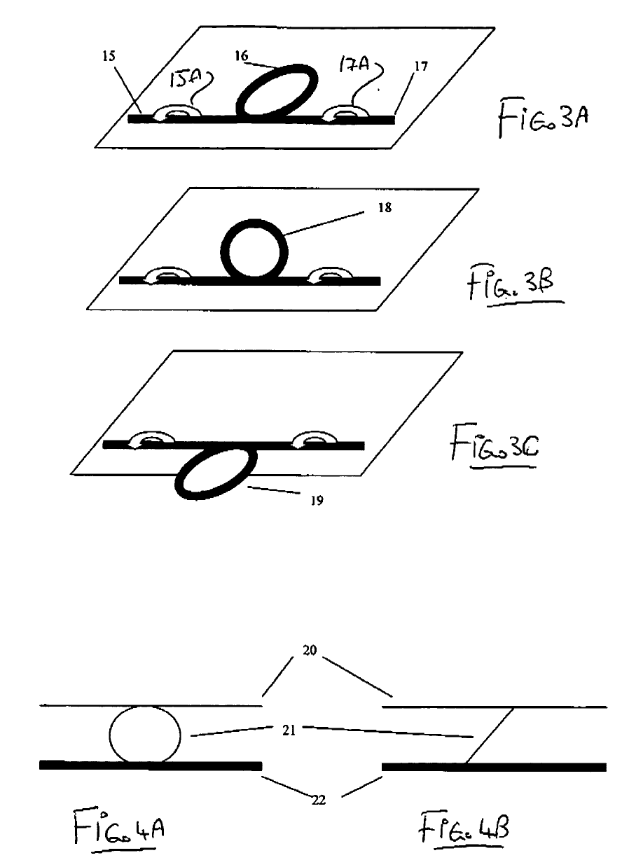

It has been demonstrated by LeFevre in the above patent, that a polarization controller can be constructed by assembling a so-called LeFevre Loop, illustrated in FIGS. 3A, 3B and 3C. In a LeFevre Loop, an optical fiber is coiled so as to form one or more turns in a loop 16 lying in a common plane which is coplanar with tangential portions 15 and 17 at one side of the loop 16. If the coil is then rotated around the axis defined by the tangential portions 15 and 17 this acts to form twists in the portions 15 and 17 as indicated at 15A, 17A. The dimensions of the loop are selected relative to the wavelength of the light and desired polarization sensitivity.

As the loop is rotated, to the positions 18 and 19 shown in FIGS. 3A and 3B, about the axis of the fiber, the SOP of the light also rotates in a manner explained in detail in the above patent.

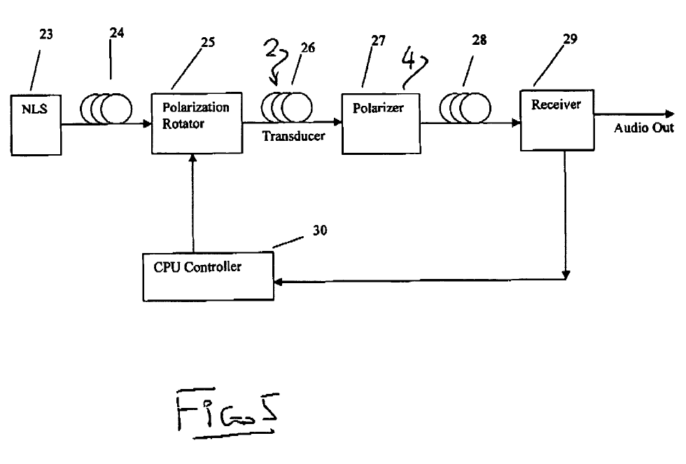

In FIG. 4 the mounting of the loop in a transducer is shown where the loop indicated at 21 is attached between a fixed base 22 and a diaphragm 20. Diaphragm motion, such as caused by sound waves, causes a rotation in the coil 21 about the legs 15 and 17 attached to either the diaphragm or to the fixed base and thus causes shifts in SOP. The amount of rotation is proportional to the amplitude of the displacement of the diaphragm and thus to the amplitude of the sound waves. The LeFevre loop is one example of a construction which can be used and it will be appreciated that other constructions can be used where one part of the single mode fiber is attached to the diaphragm and another part is fixed so that the relative movement causes twisting of a portion of the fiber to affect the SOP.

The amplitude of the signal will also be impacted by macro- and micro-bending the fiber in the formation of the loop. There is a component of attenuation loss in the LeFevre Loop, this improves signal strength of the transducer. The diaphragm both compresses and rotates the loops of fiber in the transducer. The physical fiber loop rotation is the dominant cause of rotation in state of polarization, the compression primarily affects attenuation. The two together increase the signal level over that of either alone.

As shown in FIG. 5, an alternative arrangement is proposed which acts to localize the effects of the sound waves onto the transducer component of the fiber and minimizes the effects on lead-in and lead-out portions of the fiber. Thus the transducer can be localized by replacing the Polarized Light Source of FIGS. 1 and 2 with a Non-Polarized Light Source (NLS) 23 such as, but not limited to an Erbium Doped Fiber Amplifier (EDFA) which contains an element of white noise caused by spontaneous emission, and that random output has a scattered state of polarization. This allow delivery of a non-polarized signal of useful amplitude to be delivered to a remote polarizer. Using this source, a polarizer 25 is located between the lead-in fiber 24 and the transducer 2 ideally as near as possible to the transducer 2. The effect of this is to create a polarized light source at the input to the transducer, and remove any microphonic effects of the lead-in fiber 24. The polarizer 25 could either be pre-aligned orthogonal to the receiving polarizer 4, or the rotatable polarizer 25 could be controlled by a controller 30 for initial or periodic tuning.

The return fiber 28 will be microphonic, that is responsive to vibrations, in this configuration, but this effect can be minimized by using as the lead-out fiber 28 a multimode fiber rather than a single mode fiber. The vibration sensitivity of the birefringence of a single mode fiber is not present in the multimode. The signal reaching the receiver 29 will be that impingent upon the transducer 2 alone.

A further use of this system is to use any of the above configurations as a vibration sensor by coupling the transducer fiber to a mechanical device to be monitored.

In further alternative arrangements (not shown), the light source can be modulated at a frequency chosen to cause minimum interference with the intelligence (out of band), and detected at the receiver 4 and processor 6 by detecting that frequency with equipment such as, but not limited to, a phase-locked loop, lock-in amplifier, or other synchronous detection system. In this arrangement, the rotatable polarizer 25 can be adjusted to maintain the required polarization angle of the input into the transducer in a closed loop by detection of the out of band signal. Lasers are very stable narrow spectral width sources, and as such are very sensitive to interference. High frequency modulation introduces a virtual broadening in coherence and minimizes the incident of cancellations and standing waves. This causes an audible improvement.

The effective spectral width of the PLS in the above can be broadened, such as but not limited to high frequency modulation of the laser. The effect of this is an improvement in the fidelity of the detected signal.

Since various modifications can be made in my invention as herein above described, and many apparently widely different embodiments of same made within the spirit and scope of the claims without department from such spirit and scope, it is intended that all matter contained in the accompanying specification shall be interpreted as illustrative only and not in a limiting sense.

1. An apparatus comprising:
a vibration responsive member arranged to receive vibrations to be monitored;
a fixed base member;
an optical fiber having a detection portion mounted between the base member and the vibration responsive member;
a source of light for transmission along the fiber and through the portion;
the portion of the fiber being arranged such that vibration of the vibration responsive member relative to the base member causes changes in the light transmitted through the portion;
an electronic sensor at an end of the fiber downstream of the detection portion arranged to detect the changes in the light and convert the changes into an output signal representative of the vibrations monitored.

2. The apparatus according to claim 1 wherein the apparatus is a microphone for detecting acoustic vibrations, wherein the vibration responsive member is a diaphragm and wherein the electronic sensor is arranged to emit an electronic audio signal.

3. The apparatus according to claim 1 wherein the fiber is a single mode fiber, wherein the light is polarized and wherein the detection portion of the fiber connected between the vibration responsive member and the base member is arranged such that the vibrations cause a twist in a part of the fiber so as to change polarization of the light.

4. The apparatus according to claim 3 wherein the detection portion of the single mode fiber comprises a coil and parts of the fiber either side of the coil such that movement of the coil causes twist in the parts.

5. The apparatus according to claim 4 wherein the coil is planar with tangential legs thereof forming the parts where the legs are attached to one of the base member and the vibration responsive member and a part of the coil diametrically opposite the legs is attached to the other such that the vibration causes twisting of the legs.

6. The apparatus according to claim 3 wherein the source comprises a source of polarized light and a transport portion of the fiber which carries the polarized light to the detection portion.

7. The apparatus according to claim 3 wherein the source comprises a source of non-polarized light and a transport fiber which carries the polarized light to the detection portion and wherein there is provided a polarizer between the transport fiber and the detection portion of the fiber so as to create a polarized light source at the input to the detection portion and to remove any effects of vibration on the transport fiber.

8. The apparatus according to claim 7 wherein the polarizer is a rotatable polarizer controlled by a controller for initial or periodic tuning of the angle of polarization of the light.

9. The apparatus according to claim 3 wherein the electronic sensor includes a polarizer arranged such that the intensity of light transmitted thereby changes as the polarization of the light passing through the detection portion changes.

10. The apparatus according to claim 9 wherein the polarizer is arranged such that the intensity of light passing therethrough is at a minimum when the detection portion is undistorted by vibration.

11. The apparatus according to claim 9 wherein there is provided an optical splitter downstream of the detection portion which feeds two signals into a pair of optical polarizers whose state of polarization is aligned orthogonal to each other and wherein the polarization of the light from the source is tuned such that the intensity output of one polarizer is at a maximum signal when the detection portion is undistorted by vibration and thus aligned with the polarization of the source and such that the other polarizer is at a minimum and thus orthogonal to the polarization of the source and wherein the other polarizer is used to detect the changes in polarization caused by the vibration.

12. The apparatus according to claim 3 wherein there is provided a return portion of fiber extending from the detection portion to the electronic sensor and wherein the return portion is a multimode fiber rather than single mode fiber so as to remove any effects of vibration on the return fiber.

13. The apparatus according to claim 3 wherein the fiber is also sensitive to attenuation caused by compression so that the diaphragm both compresses and rotates the fiber to increase the signal level over that of the rotation alone.
